(19) United States
(12) Patent Application Publication
(10) Pub. No.: US 2025/0279324 A1
(43) Pub. Date: Sep. 4, 2025

(54) PACKAGE WITH CARRIER HAVING COMPONENT ACCOMMODATION VOLUME ON ONE SIDE AND REPELLING STRUCTURE ON OTHER SIDE

(71) Applicant: Infineon Technologies AG, Neubiberg (DE)

(72) Inventors: Hugo BURKE, Cardiff (GB); Mark PAVIER, East Grinstead (GB); Clive O'DELL, Horley (GB)

(73) Assignee: Infineon Technologies AG, Neubiberg (DE)

(21) Appl. No.: 19/033,079

(22) Filed: Jan. 21, 2025

(30) Foreign Application Priority Data
Mar. 4, 2024 (DE) 10 2024 202 000.1

(51) Int. Cl. H01L 23/24; H01L 21/48; H01L 21/52; H01L 23/00; H01L 23/06; H01L 23/367

(52) U.S. Cl. CPC H01L 23/24; H01L 21/4867; H01L 23/06; H01L 23/3675; H01L 24/32; H01L 21/52; H01L 23/3672; H01L 24/16; H01L 24/73; H01L 2224/16227; H01L 2224/32245; H01L 2224/73253

(57) ABSTRACT

A package is disclosed. In one example, the package comprises an at least partially electrically conductive carrier which is formed for delimiting an accommodation volume therein, an electronic component mounted on the carrier and accommodated at least partially in the accommodation volume, and a repelling structure. In one example, the repelling structure is configured for repelling an electrically conductive connection medium and being arranged on part of a surface of the carrier facing away from the accommodation volume.

### CROSS-REFERENCE TO RELATED APPLICATION

This Utility patent application claims priority to German Patent Application No. 10 2024 202 000.1 filed Mar. 4, 2024, which is incorporated herein by reference.

### BACKGROUND

### Technical Field

Various embodiments relate generally to a package, an electronic device, and a manufacturing method.

### Description of the Related Art

A conventional package may comprise a semiconductor component mounted on a carrier such as a leadframe structure, may be electrically connected by a bond wire extending from the semiconductor component to the carrier, and may be molded using a mold compound as an encapsulant.

However, also non-encapsulated packages exist such as a DirectFET® package in which a semiconductor chip is accommodated in an accommodation volume of a carrier.

A proper combination of electric reliability and thermal performance may still be a challenge.

### SUMMARY

There may be a need for a package with high electric reliability and high thermal performance.

According to an exemplary embodiment, a package is provided which comprises an at least partially electrically conductive carrier which is formed for delimiting an accommodation volume therein, an electronic component mounted on the carrier and accommodated at least partially in the accommodation volume, and a repelling structure configured for repelling an electrically conductive connection medium and being arranged on part of a surface (in particular an exterior surface) of the carrier facing away from the accommodation volume.

According to another exemplary embodiment, an electronic device is provided which comprises a package having the above mentioned features, and an assembly structure assembled with the package.

According to still another exemplary embodiment, a method of manufacturing a package is provided, wherein the method comprises providing an at least partially electrically conductive carrier which is formed for delimiting an accommodation volume therein, mounting an electronic component on the carrier and accommodated at least partially in the accommodation volume, forming a repelling structure configured for repelling an electrically conductive connection medium, and arranging the repelling structure on part of a surface of the carrier facing away from the accommodation volume.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a cross-sectional view of an electronic device with a package according to an exemplary embodiment.

FIG. 2 illustrates a cross-sectional view of the package of the electronic device according to FIG. 1.

FIG. 3 illustrates a plan view of the package according to FIG. 2.

FIG. 4 illustrates a cross-sectional view of a package according to another exemplary embodiment.

FIG. 5 illustrates a plan view of the package according to FIG. 4.

FIG. 6 illustrates a cross-sectional view of a package according to another exemplary embodiment.

FIG. 7 illustrates a plan view of the package according to FIG. 6.

FIG. 8 illustrates a top-sided three-dimensional view of a carrier with indented accommodation volume of a package according to another exemplary embodiment.

FIG. 9 illustrates a bottom-sided three-dimensional view of the carrier with accommodation volume of the package according to FIG. 8.

FIG. 10 illustrates a flowchart of a method of manufacturing a package according to an exemplary embodiment.

### DETAILED DESCRIPTION

There may be a need for a package with high electric reliability and high thermal performance.

According to an exemplary embodiment, a package is provided which comprises an at least partially electrically conductive carrier which is formed for delimiting an accommodation volume therein, an electronic component mounted on the carrier and accommodated at least partially in the accommodation volume, and a repelling structure configured for repelling an electrically conductive connection medium and being arranged on part of a surface (in particular an exterior surface) of the carrier facing away from the accommodation volume.

According to another exemplary embodiment, an electronic device is provided which comprises a package having the above mentioned features, and an assembly structure assembled with the package.

According to still another exemplary embodiment, a method of manufacturing a package is provided, wherein the method comprises providing an at least partially electrically conductive carrier which is formed for delimiting an accommodation volume therein, mounting an electronic component on the carrier and accommodated at least partially in the accommodation volume, forming a repelling structure configured for repelling an electrically conductive connection medium, and arranging the repelling structure on part of a surface of the carrier facing away from the accommodation volume.

According to an exemplary embodiment, a package is equipped with an at least partially electrically conductive carrier which may be formed to delimit a preferably flat interior surface surrounded by walls for defining an accommodation volume in which an electronic component may be located and fixed. Advantageously, a repelling structure (for instance a solder resist) for repelling an electrically conductive connection medium (such as a solder) may be provided on an exterior surface portion of the carrier opposing the interior accommodation volume. This may make it possible to connect an assembly structure (such as a heat sink) on the exterior surface portion opposing the accommodation volume without the risk that electrically conductive connection medium used for connecting the assembly structure on the carrier flows from the exterior surface of the carrier into its interior surface and towards the electronic component, since this may be reliably prevented by the repelling structure. Avoiding undesired flow of electrically conductive connection medium into undesired regions of the package may lead to a proper electric reliability. The possibility to establish a thermally highly conductive link of a heat sink via the electrically conductive connection medium and the back side of the at least partially electrically conductive carrier to the main heat source in form of the accommodated electronic component may ensure a high thermal performance. To put it shortly, the described configuration may make it possible to solder a heat sink to the back side of the component-accommodating carrier without the risk of undesired solder flow along a possibly wettable exterior surface of the carrier towards the accommodation volume.

### DESCRIPTION OF FURTHER EXEMPLARY EMBODIMENTS

In the following, further exemplary embodiments of the package, the electronic device and the method will be explained.

In the context of the present application, the term “package” may particularly denote an arrangement which may comprise one or more packaged electronic components. A partially or entirely electrically conductive carrier may form part of the package as well. Said constituents of the package may be non-encapsulated, or may be encapsulated at least partially by an encapsulant. Optionally, one or more electrically conductive connection elements (such as metallic pillars, bumps, bond wires and/or clips) may be implemented in a package, for instance for electrically coupling and/or mechanically supporting the electronic component.

In the context of the present application, the term “carrier” may particularly denote a support structure (which may be at least partially electrically conductive) which serves as a mechanical support in a package, and which may also contribute to the electric interconnection between one or more electronic components and the periphery of the package. In other words, the carrier may fulfil a mechanical support function and/or an electric connection function. A carrier may comprise or consist of a single part, multiple parts joined via encapsulation or other package components, or a subassembly of carriers. When the carrier forms part of a leadframe, it may be or may comprise a die pad. For instance, the carrier may be embodied as an electrically conductive plate, in particular made of a metal such as copper, aluminium or the like, which may be a bent for defining the accommodation volume for the electronic component. An indented section of the carrier may form the accommodation volume, whereas an opposing outdented section of the carrier may delimit a heat removal surface for mounting a heat sink thereon.

In the context of the present application, the term “carrier formed for delimiting an accommodation volume” may particularly denote a carrier which can be bent, for example three dimensionally bent, so as to define a cavity, hollow space or any other kind of free volume therein which allows to mount an electronic component on the carrier and in said accommodation volume. For example, such a carrier for delimiting an accommodation volume may be formed by bending a metallic plate. For instance said bending may be of such a type that a can-shaped carrier for delimiting an accommodation volume may be obtained.

In the context of the present application, the term “electronic component” may in particular encompass a semiconductor chip (in particular a power semiconductor chip), an active electronic device (such as a transistor), a passive electronic device (such as a capacitor or an inductor or an ohmic resistor), a sensor (such as a microphone, a light sensor, a temperature sensor or a gas sensor), an actuator (for instance a loudspeaker), and a microelectromechanical system (MEMS). However, in other embodiments, the electronic component may also be of different type, such as a mechatronic member, in particular a mechanical switch, etc. In particular, the electronic component may be a semiconductor chip having at least one integrated circuit element (such as a diode or a transistor in a surface portion thereof). The electronic component may be a bare die or may be already packaged or encapsulated. Semiconductor chips implemented according to exemplary embodiments may be formed for example in silicon technology, gallium nitride technology, silicon carbide technology, etc.

In the context of the present application, the term “repelling structure configured for repelling an electrically conductive connection medium” may particularly denote a physical structure which is made of a material and which is arranged at a position that flow of an electrically conductive connection medium (such as a solder, a sinter or an electrically conductive glue) along the repelling structure is strongly inhibited or even disabled. For instance, the repelling structure may be made of a material having repellent or non-wetting properties for the electrically conductive connection medium. For example, the repelling structure may be a solder resist when the electrically conductive connection medium is a solder. For instance, the non-wetting properties of the repelling structure may be at least more pronounced than for surrounding material of the package. It may be desired that the repelling structure is annularly closed so as to maintain the electrically conductive connection medium within an area defined by the fence-like annularly closed repelling structure. However, it may also be possible in other embodiments to configure the repelling structure not as a ring, but as one or a plurality of individual physical structures functioning as a mechanical and chemical barrier for the electrically conductive connection medium.

In the context of the present application, the term “electrically conductive connection medium” may particularly denote a material which is capable of conducting electric current, which is preferably also capable of conducting heat, and which additionally has properties to connect the carrier with an electronic component and/or with an assembly structure, such as a heat sink and/or a mounting board (such as a printed circuit board, PCB). Examples for the electrically conductive connection medium are a solder, a sinter paste, and/or an electrically conductive glue (for instance a glue comprising metallic particles therein). The connection medium may be a material which may be configured for, preferably mechanically and electrically, connecting different constituents with each other. Such a connection medium may be flowable during processing, and may be rendered (in particular permanently) solid by hardening, curing or the like. Examples for a connection medium are a solder, a glue or an assembly adhesive, or even a sinterable or semi-sinterable material.

In the context of the present application, the term “electronic device” may particularly denote a device with electronic functionality and which may comprise a package with one or more electronic components and a carrier as well as one or more exposed electrically conductive structure(s) (such as pads, terminals, leads, etc.). The electronic device may have a mounting base carrying said package and/or may have a heat sink mounted on the package, i.e. at least one assembly structure.

In the context of the present application, the term “assembly structure” may particularly denote a structure being electrically and/or mechanically and/or thermally coupled with the package. For instance, such an assembly structure may comprise a mounting base (which may be, for example, a printed circuit board (PCB)). The package may be surface mounted on the mounting base. Additionally or alternatively, the assembly structure may comprise a heat sink attached to the package for removing heat generated by the package, for instance predominantly generated by the at least one electronic component of the package, during operation.

In the context of the present application, the term “main surface” of a body may particularly denote the largest body surface of one of the largest body surfaces. For instance, a body (such as a carrier or an electronic component) may have two opposing main surfaces separated by body material in a thickness direction and connected with each other by a circumferential edge.

In an embodiment, the package comprises a wettable coating (in particular a solderable plating) configured for being wettable by an electrically conductive connection medium and being arranged at least on part of a heat removal surface (in particular an exterior heat removal surface, which may be planar) of the carrier facing away from the accommodation volume. In other words, the wettable coating may be formed at least on a surface portion of the carrier which opposes the concave side of the carrier with the accommodation volume. More specifically, the wettable coating may be formed on the heat removal surface, which may be a top-sided exterior planar surface of the carrier.

Advantageously, this may allow to establish a solder connection between the heat removal surface and a heat sink, since the solder may properly wet the wettable coating.

Advantageously, the repelling structure may prevent flowable electrically conductive connection medium from flowing away from the heat removal surface, for instance to an underside of the carrier.

In the context of the present application, the term “wettable coating” (such as a wettability layer) may particularly denote a film or sheet having a surface property promoting wetting by a (for example flowable during processing) electrically conductive connection medium (such as solder or adhesive) thereon. In particular, wetting may denote the ability of an electrically conductive connection medium to maintain contact with a solid surface of the wettable coating, in particular resulting from intermolecular interactions when the two are brought together. The degree of wetting may be denoted as wettability and may be determined by a force balance between adhesive and cohesive forces.

In an embodiment, the wettable coating also coats at least part of a surface of the carrier facing away from the heat removal surface and delimiting the accommodation volume. Thus, a wettable coating may also be present at a concave surface of the carrier. Advantageously, this may allow to establish a solder connection between the surface of the wettable coating on the carrier in the accommodation volume and the electronic component to be mounted on the wettable carrier in the accommodation volume.

In an embodiment, the wettable coating coats an entire exterior surface of the carrier. This may allow to form the wettable coating on the entire surface of the carrier with a single common manufacturing process, for instance plating, without the necessity of selective plating or patterning of the wettable coating. Thanks to the repelling structure on the wettable coating, a full-surface covering wettable coating will allow a solder flow only in allowed regions, because the repelling structure may act as a mechanical and/or chemical barrier for such a solder flow.

In an embodiment, the wettable coating is configured for wetting a solder-type electrically conductive connection medium. Alternatively, the wettable coating may be configured for wetting an electrically conductive glue or a sinter material.

In an embodiment, the wettable coating is a plating layer. A plating layer may be a layer formed at least partially by plating, for example by depositing a metal on a surface (for instance by electroless plating or sputtering). It is possible to do plating directly on the carrier, such as a leadframe or a clip.

In an embodiment, the wettable coating comprises or consists of silver. Silver may have excellent wetting properties, so that a solder may be distributed homogeneously over a silver surface. Advantageously, silver plating may provide a better wetting than other materials (such as copper).

In an embodiment, the wettable coating comprises silver and/or nickel. In particular, the coating may be a double layer comprising a bottom-sided nickel layer on the carrier and a top-sided silver layer on the nickel layer. Nickel is solderable, hard and keeps the color. Silver is also solderable, reduces the risk of copper migration, may prevent nickel from oxidizing and has a pronounced wetting function. To put it shortly, a wettable coating which comprises silver and nickel may form an excellent solderable film.

In another embodiment, the wettable coating comprises or consists of one of the group comprising palladium, gold, titanium, nickel, and NiP.

Although the materials of the wettable coating mentioned in the previous paragraphs may be preferred choices, the wettable coating can be made of any material with affinity to an implemented electrically conductive connection medium (in particular a solder).

In an embodiment, the repelling structure is formed at least on at least part of each of two opposing rails of the carrier. When formed at least partially on said rails, undesired bleeding, creeping or flow of flowable electrically conductive connection medium from the top side to the bottom side of the carrier via the rails may be reliably prevented.

In an embodiment, the repelling structure comprises a closed annular structure. According to such a preferred embodiment, the repelling structure may form a circumferentially closed ring preventing unintentional bleeding, creeping or flow of flowable electrically conductive connection medium out of the spatial range delimited by said annular structure or ring. A full perimeter protection against undesired spreading of flowable electrically conductive connection medium may thus be ensured.

In an embodiment, the repelling structure comprises a solder resist. A solder resist or solder mask may be a strip, web, or layer of an ink, a polymer, a paste, a laminate or a lacquer or any other dielectric material that is applied to a surface to prevent solder bleeding or formation of solder bridges. A solder resist may also function for preventing oxidation. For instance, a solder resist may be formed based on an epoxy resin. For instance, the repelling structure may be embodied as an epoxy mask.

In an embodiment, the repelling structure is arranged on the wettable coating. When forming the repelling structure directly on the wettable coating, flowable electrically conductive connection medium (for instance molten solder) flowing along the path of a wettable coating may be directly stopped by the chemical and mechanical barrier in form of the repelling structure.

In an embodiment, the repelling structure is arranged on an exterior surface of a transition portion between a, preferably planar, exterior heat removal surface of the carrier and an interior surface of the carrier delimiting the accommodation volume. In view of such a preferred configuration, the entire area of the (preferably flat) exterior heat removal surface adjacent to the transition portion (preferably a slanted, stepped or vertical edge portion of the carrier) may remain available for heat removal, for instance for soldering a heat sink thereon. Moreover, when arranged on the transition portion, the repelling structure may be spatially retracted and thus properly protected against damage.

In an embodiment, the transition portion of the carrier is curved and/or stepped. For example, the transition portion may comprise a plurality of steps and/or a plurality of curved sections, and may also comprise one or more horizontal platforms. By this curved and/or stepped configuration of the transition portion, the interior thereof may laterally delimit the accommodation volume, whereas the exterior thereof may function as a support surface for the repelling structure.

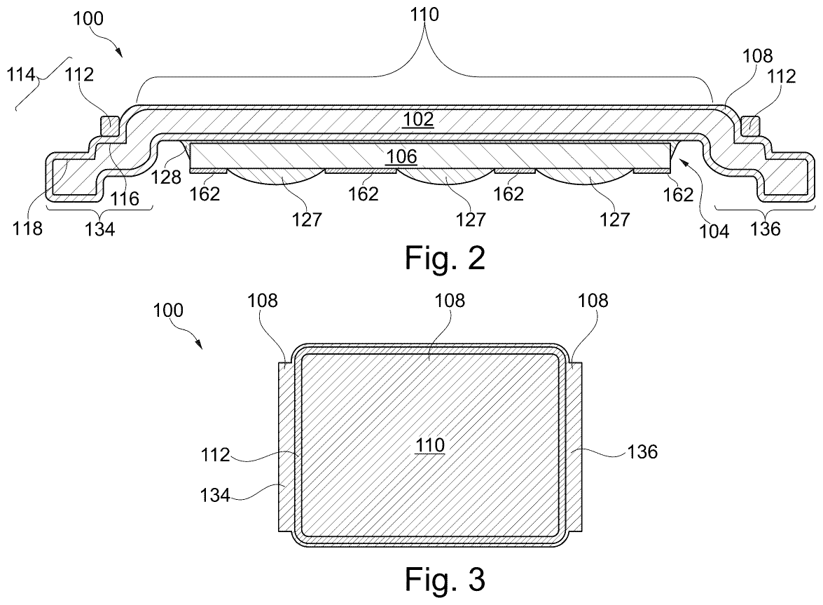

In an embodiment, the repelling structure is arranged on a platform (which may be a horizontal platform), in particular on an upper platform (preferably on an uppermost platform), of the transition portion retracted downwardly with respect to the heat removal surface (see for example FIG. 2). According to such a preferred embodiment, the entire heat removal surface remains available for heat removal purposes while the repelling structure may be nevertheless formed very close to the upper main surface of the carrier to thereby reliably prevent or limit flow of flowable electrically conductive connection medium out of this area. In other words, solder flow may be spatially confined to the heat removal surface, and flow of molten solder to the bottom portion of the transition region may also be disabled by the repelling structure.

In an embodiment, the repelling structure extends from the upper (or uppermost) platform up to and including (in particular partially or entirely) a lower (or lowermost) platform of the transition portion (see for example FIG. 4). By such a spatially extended configuration of the repelling structure and by the corresponding complex shape of the repelling structure extending between different platforms and thus different height levels of the transition portion, a complicated and elongate flow path is formed which makes it almost impossible for flowable electrically conductive connection medium to pass this complex mechanical and chemical barrier. Moreover, said barrier may also be complex enough to even avoid or at least inhibit undesired creepage of moisture or the like along the transition portion.

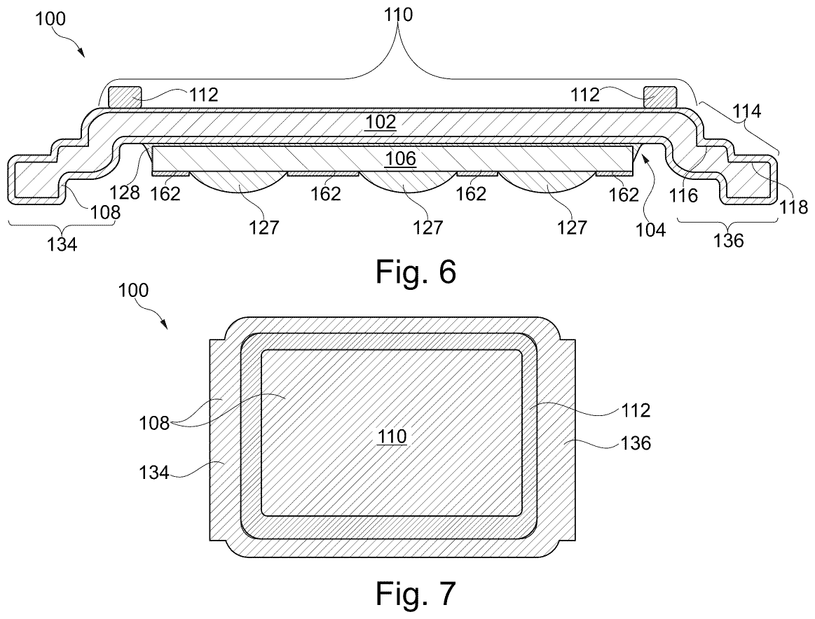

In an embodiment, the repelling structure is arranged on a planar area of the heat removal surface (see for example FIG. 6). For example, the repelling structure may form a ring extending along the upper exterior surface of the carrier. Such a configuration allows a particularly simple manufacture of the repelling structure on an easily accessible planar surface area. In order to keep the heat removal surface of the carrier as large as possible, the repelling structure may then be formed along an exterior perimeter of the planar heat removal surface.

In an embodiment, the electronic component comprises at least one carrier-connected terminal on one main surface on which the electronic component is mounted on the carrier. It is also possible that a plurality of carrier-connected terminals are provided.

In an embodiment, the electronic component comprises at least one exposed terminal, for example a plurality of exposed terminals, facing away from the carrier. For example, said exposed terminals may be arranged side-by-side.

It is also possible that the electronic component comprises terminals on both opposing main surfaces thereof. For instance, the electronic component may be a semiconductor die experiencing, during operation, a vertical current flow between terminals on both of its two opposing main surfaces.

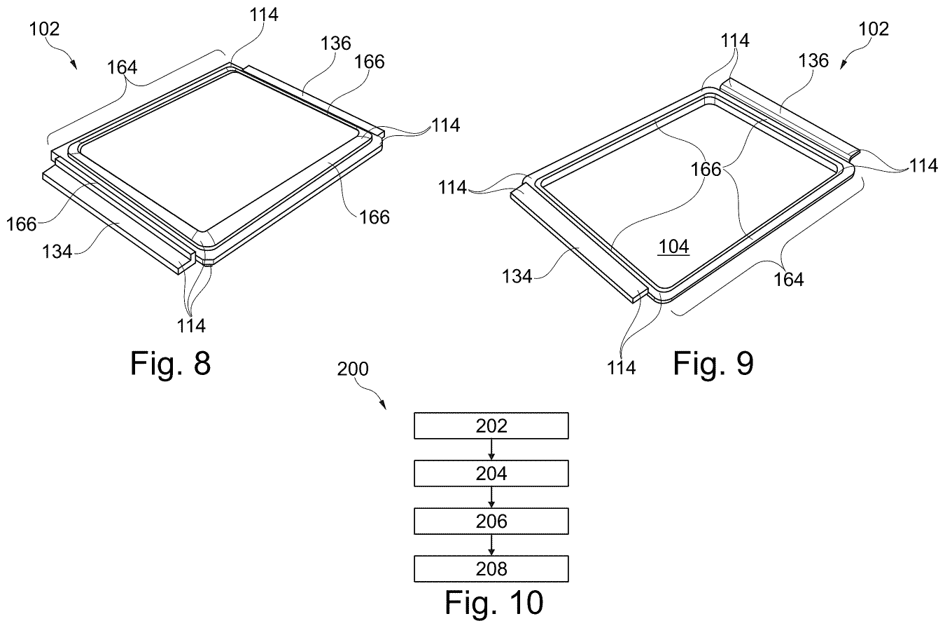

In an embodiment, the carrier is can-shaped and/or has two opposing rails (see for example FIG. 8 and FIG. 9). Based on such a carrier, a package of the DirectFET® type can be manufactured.

In an embodiment, the carrier comprises a leadframe structure, a clip and/or a bent metallic plate.

In the context of the present application, the term “leadframe structure” may particularly denote a sheet-like metallic structure which can be bent, punched and/or patterned so as to form leadframe structures as mounting sections for mounting chips. In an embodiment, the leadframe may be a metal plate (in particular made of copper or an alloy containing copper) which may be bent and/or patterned. Forming the carrier as a leadframe structure is a cost-efficient and mechanically as well as electrically highly advantageous configuration in which a low ohmic connection of chips can be combined with a robust support capability of the leadframe structure. Furthermore, a leadframe structure may contribute to the thermal conductivity of the package and may remove heat generated during operation of the chip(s) as a result of the high thermal conductivity of the metallic (in particular copper) material of the leadframe structure. In the context of the present application, the term “clip” may particularly denote a three-dimensionally curved connection element which comprises an electrically conductive material such as copper and is an integral body with sections to be connected to chip terminals and/or a mounting base.

In an embodiment, the package is configured as a discrete package. In particular, the package may comprise a single electronic component. However, in another embodiment, the package may comprise a plurality of electronic components mounted on the same carrier. Thus, the package may also comprise a plurality of semiconductor components mounted in the accommodation volume. Thus, the package may comprise one or more semiconductor components (for instance at least one passive component, such as a capacitor, and at least one active component).

In an embodiment, the package is configured as a non-encapsulated package. Thus, the package may be free of an encapsulant. Alternatively, the package may comprise an encapsulant such as a mold compound.

In an embodiment, the package is configured as a power package. For instance, the package is configured as a semiconductor power package. For instance, an exemplary embodiment of the package may be an intelligent power module (IPM). Another exemplary embodiment of the package is a dual inline package (DIP). For instance, such a DIP may comprise multiple leads on the can-shaped carrier. For example, the can may be placed over and insulated from the leads of the DIP.

In an embodiment, the electronic component is a power semiconductor chip. Thus, the semiconductor component (such as a semiconductor chip) may be used for power applications (for instance in the automotive field) and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide or gallium nitride). A semiconductor power chip may comprise one or more field effect transistors, diodes, inverter circuits, half-bridges, full-bridges, drivers, logic circuits, further devices, etc.

In an embodiment, the electronic component comprises a monolithically integrated transistor, in particular a field-effect transistor. Other transistors are possible, for instance a bipolar transistor.

In an embodiment, the electronic device comprises an electrically conductive connection medium electrically connecting the package with the assembly structure. For example, the electrically conductive connection medium comprises a solder, a sinter material and/or an electrically conductive glue.

In an embodiment, the electrically conductive connection medium comprises a solder. In the context of the present application, the term “solder” may be a solderable material which can be subjected to soldering to thereby establish an electrically conductive solder connection between different constituents. For instance, such a solder structure may be a film or layer of solder or may be a solder bump. For example, it is possible to use a solder paste with lead-based or bismuth-based solder materials. It may also be possible to use a solder structure comprising tin.

In an embodiment, the electrically conductive connection medium comprises an assembly adhesive, for example an electrically conductive glue. It is also possible that such an assembly adhesive may be a die attach paste. The assembly adhesive may also be any resin-based assembly adhesive, including semi-sintering materials and pressure based sintering materials. What concerns hybrid and semi-sintering materials, a corresponding paste may be a partially adhesive and partially sintering paste, for example a silver filled adhesive. Thus, an assembly adhesive may be resin based, while pure sintering products may be solvent based. They can be handled with the same or similar processes as other die attach adhesives. Hence, all resin-based die attach or assembly materials can be used as the connection medium. For example, the assembly adhesive can be epoxy based, or based on acrylic, silicone, Bismaleimides (BMI) and/or hybrid materials.

In an embodiment, the assembly structure comprises a heat sink mounted on a heat removal surface of the carrier. In the context of the present application, the term “heat sink” may in particular denote a highly thermally conductive body which may be thermally coupled with the exposed carrier of the package for removing heat generated by the electronic component(s) during operation of the package. For example, the heat sink may be made of a material having a thermal conductivity of at least 10 W/mK, in particular at least 50 W/mK, even up to 400 W/mK or even above. For instance, the heat sink may be made of an electrically conductive material such as copper, an alloy of copper and/or aluminium, but may also comprise a ceramic material. The heat sink may be directly or indirectly thermally coupled with the carrier, for instance by a solder. For example, the heat sink may comprise a thermally conductive body (such as a metal plate) with a plurality of cooling fins extending from the thermally conductive body. Additionally or alternatively, liquid and/or gas cooling may be accomplished by a heat sink as well. The thermal coupling of the package with a heat sink may ensure an efficient cooling.

In an embodiment, the assembly structure comprises a mounting base, for example a laminate board, on which the carrier and/or the electronic component is or are mounted. For instance, the mounting base may be a printed circuit board (PCB), an Insulated Metal Substrate (IMS), a Direct Copper Bonding (DCB) Substrate or an Active Metal Brazing (AMB) substrate. As an alternative to a printed circuit board, also another kind of laminate carrier may be implemented as mounting base.

For instance, the package may be sandwiched between a mounting base and a heat sink. For instance, rails of the carrier may be solder-connected with the mounting base. It is also possible that an exposed main surface of the electronic component mounted in the accommodation volume of the carrier is solder-connected with a mounting base. Thus, the mounting base may form a bottom-sided body of the electronic device. A heat sink may be soldered on top of the upper main surface of the carrier facing away from the accommodation volume and may therefore form a top-sided body of the electronic device.

In an embodiment, the method comprises forming the repelling structure by printing, for example inkjet printing or three-dimensional printing, optionally followed by curing. In this way, the repelling structure can be manufactured in a simple and precise way. Moreover, by using ink jet printing it may also be possible to increase the thickness of the coating by applying multiple layers on top of each other.

As substrate or wafer forming the basis of the semiconductor component(s), a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

A DirectFET® package may comprise a can-shaped metallic carrier having at least one surface mounted electronic component, such as one or more power MOSFET devices. Solderable contacts on the surface of the silicon die may be provided for connecting gate and source to a printed circuit board (PCB). A copper clip attached to the back of the die may provide the drain connection.

A conventional DirectFET® package may be provided with a silver coating on its underside or internal side only to enable silver epoxy adhesion. For example, a Ni/Ag coating may be applied on the inside surface of the carrier. This may promote proper mounting of the electronic component on the carrier. However, silver is kept off the top side of the carrier to prevent tarnishing and excess potential for silver migration.

According to an exemplary embodiment, a package (which may be of a non-encapsulated type) may comprise a (for instance metallic) carrier having an accommodation volume on its front or bottom side for accommodating an electronic component (for example a semiconductor chip). Beneficially, a (for instance annular) repelling structure may be provided as a barrier for repelling an electrically conductive connection medium and may be formed on an exterior surface portion of the carrier's back side facing away from the accommodation volume. Preferably, the repelling structure for repelling an electrically conductive connection medium may be a solder resist for repelling solder. Consequently, electrically conductive connection medium (such as solder), which may for instance be applied for connecting a heat sink or another assembly structure on the back side of the carrier may be reliably prevented from wetting a front side surface portion of the carrier in which the electronic component may be mounted. As a result, a good electric reliability may be achieved since the repelling structure may help to keep electrically conductive connection medium in target regions only. At the same time, proper heat removal may be ensured by the opportunity to solder-connect a heat sink on the back side of the at least partially metallic carrier. This may lead to an excellent performance of the package. For example, the described package may advantageously allow to solder a heat sink to the back side of the carrier while reliably preventing unintentional solder flow up to the front side with the electronic component mounted in the accommodation volume.

According to an exemplary embodiment, a repelling structure configured as a solder mask may be applied on a wettable coating for forming a silver back package with protection against solder bleeding. For example, such a solder mask may enable a solder-connection of a heat sink which may be connected on the back side of the carrier facing away from the electronic component mounting side thereof. Advantageously, it may be in particular possible to provide a silver backed DirectFET®-type package with a repelling structure functioning as a solder keep out zone to enable soldering (for instance of a heat sink) to the back of a can-shaped carrier.

For promoting transition of heat through the top of a DirectFET® package, a heat sink can be added. Doing this using a non-electrically conducting TIM (thermal interface material) is conventionally an option, although the thermal coupling may be limited by the low thermal conductivity of the TIM. However, soldering the heat sink to the can-shaped carrier top may enable significantly better thermal conduction and may thus be highly preferred. However, in conventional approaches, this may lead to an undesired wetting of unintended surface portions of the carrier (for instance those facing the mounted electronic component) with solder, which may result in undefined or non-reproducible configurations involving issues concerning electrical reliability. According to an exemplary embodiment, a repelling structure, such as a solder mask, may be formed for example onto the outer rim of the carrier, preferably directly on a wettable coating. This may allow to reliably prevent a solder—or more generally an electrically conductive connection medium—from wetting the carrier surface where it is not wanted. Furthermore, this may prevent electrically conductive connection medium, such as solder, from ingressing under the can-shaped carrier and flowing where it is not desired. Thus, the electric reliability of the package may be improved by providing the described repelling structure.

At the same time, this may offer the opportunity to solder-connect a heat sink to the back side of the carrier, since the solder may be prevented by the repelling structure from flowing into undesired regions. This may lead, in turn, to a significantly improved thermal performance of the package due to the establishment of a highly efficient heat flow path from the electronic component via the carrier and the heat sink to an environment of the electronic device. By transmitting heat more efficiently, the package may run at a lower temperature improving efficiency and may require less energy to cool. This may also contribute to a reduction of carbon dioxide emission. With improved cooling, it may also enable increased operational currents as Joule heating from the device may be more effectively removed by the improved cooling allowed by exemplary embodiments.

In a preferred embodiment, the entire can-shaped carrier may be coated in nickel (Ni) and silver (Ag), which may be applied for example by plating. Although silver and in particular a silver-nickel combination may be preferred, other materials such as gold may be used as well. This may enable soldering of a heat sink to the back of the can-shaped carrier itself to improve the overall thermal capability, while simultaneously allowing to mount, by soldering, an electronic component on the front side of the carrier. To prevent wetting of solder down the edges of the can-shaped carrier and underneath the can-shaped carrier, a repelling structure such as a solder mask may be provided which, in a preferred embodiment, may sit neatly in the first downset of the can. For example, the repelling structure which may be embodied advantageously as a solder mask can be dispensed or printed. Thus, a gist of an exemplary embodiment may be to coat the entire can in silver to enable sintering, silver epoxy glue connection or soldering of a heat sink to the top of the can.

Hence, in order to prevent wetting of undesired portions of the carrier by electrically conductive connection medium (especially solder), it may be highly beneficial to provide a repelling structure such as a solder mask, preferably to the rim of the can-shaped carrier. This solder mask may prevent solder from wetting beyond and under the carrier. The mentioned positioning of the solder mask may ensure that it will not interfere with the appearance of the package or the positioning of an optional laser scribe. For example, the solder mask-type repelling structure can be applied in leadframe form using a dispense or an ink jetting process. This may contribute to an efficient manufacturing process with high throughput on an industrial scale. As a result, it may be possible to solder a heat sink to the top of the can-shaped carrier. In order to support this, it may be advantageous to add silver on the back of package with a solder mask thereon.

Thus, an exemplary embodiment provides a package (such as a discrete package, for instance a field-effect transistor (FET) package) with a metal can construction of the package's carrier. A silver coating (preferably a NiAg coating, which may be embodied as a double layer composed of a bottom-sided nickel layer and a top-sided silver layer) on the back side of the package (which may correspond to a top side of the can-shaped carrier) may be advantageously combined with a solder keep-out-zone in form of a solder resist-type repelling structure. Advantageously, an attachment of a heat sink to the back side of the package may be enabled using an electrically conductive connection medium, such as a silver filled epoxy, a sinter or a solder.

In a preferred embodiment, the repelling structure forming a solder keep-out-zone may be made by adding a solder mask to prevent overspill of solder material to the underside of the electronic component (in particular a die), thereby preventing tarnishing and excess silver migration.

Advantageously, a solder mask-type repelling structure may be added in the form of a ring that encircles the first downset of the can-shaped carrier maintaining planarity of the structure. Advantageously, reducing (in particular minimizing) a solder mask area may increase (in particular maximize) the cooling capability of the package. Also double-sided cooling may be enabled with such a package configuration.

Advantageously, a solder mask may be jetted for forming a repelling structure to cover drain edges while preventing solder from moving up to drain rails. In an embodiment, it may also be possible to jet a solder mask-type repelling structure to cover just the back side of the carrier.

To put it shortly, a solder mask-type repelling structure may inhibit bleed-out of electrically conductive connection medium, such as solder, from a top side of the carrier via sidewalls thereof downwardly and towards the electronic component. In other words, the repelling structure may prevent parasitic creepage of solder—or another electrically conductive connection medium—into undesired regions by providing a stopper—in particular a solder stopper—on the back side of the carrier, which may for instance be embodied as leadframe structure or clip. At the same time, the repelling structure may make it possible to establish a solder connection on the back side of the carrier with a heat sink, to improve thermal reliability.

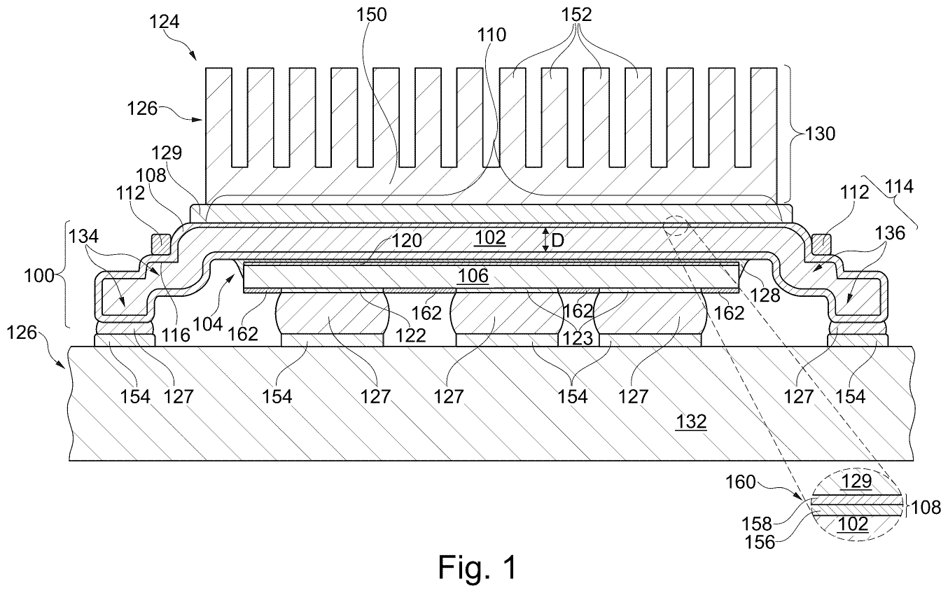

FIG. 1 illustrates a cross-sectional view of an electronic device 124 with a package 100 according to an exemplary embodiment.

The illustrated electronic device 124 comprises package 100 and an assembly structure 126 composed of two separate constituents assembled on the top side and the bottom side of the package 100, respectively.

More specifically, the top-sided constituent of the assembly structure 126 is here embodied as a heat sink 130 mounted on a heat removal surface 110 of the package 100. The heat sink 130 is configured for efficiently removing heat from the top side of the package 100. In the shown embodiment, the heat sink 130 comprises a highly thermally conductive plate 150 to be thermally coupled with the top side of the package 100. A plurality of cooling fins 152 extend in parallel to each other from the highly thermally conductive plate 150 and are integrally formed therewith. The heat sink 130 may be made of a highly thermally conductive material such as copper, aluminium or a ceramic. Other embodiments of the heat sink 130 are possible, for instance a water cooling heat sink, a fan-type heat sink, a heat sink comprising heat pipes, etc.

On a bottom side of the electronic device 124, another constituent of the assembly structure 126 is provided which is embodied as a mounting base 132, for example a laminate board such as a printed circuit board (PCB) or an interposer. A carrier 102 and an electronic component 106 of the package 100, which will be described below in further detail, are mounted mechanically and electrically on the mounting base 132.

As shown, an electrically conductive connection medium 128 electrically and mechanically connects the carrier 102 and the electronic component 106 of the package 100 with each other. Moreover, a further electrically conductive connection medium 127 electrically and mechanically connects the mounting base 132 of the assembly structure 126 with the carrier 102 and the electronic component 106. More specifically, the electrically conductive connection medium 127 connects exposed pads 154 (such as copper pads) of the PCB-type mounting base 132 with exposed terminals 122, 123 on a bottom main surface of electronic component 106 of package 100 and connects further exposed pads 154 with the carrier 102. Correspondingly, another electrically conductive connection medium 129 electrically and mechanically connects the carrier 102 of the package 100 with the heat sink 130 of the assembly structure 126. In the shown embodiment, the electrically conductive connection medium 128 comprises is for instance a silver filled epoxy or hybrid sinter paste, or a diffusion solder joint. For example, the electrically conductive connection medium 129 can be a solder such as SAC (Sn/Ag/Cu) alloy. For instance, the electrically conductive connection medium 127 can be another or the same solder. More generally, the electrically conductive connection medium 127, 128, 129 may be different or may be the same. For example, the electrically conductive connection medium 127 and/or 128 and/or 129 may be a solder, a sinter material (such as a sinter paste) and/or an electrically conductive glue (for example an epoxy-based glue with metallic particles therein). The mentioned connections established by the electrically conductive connection media 127, 128, 129 ensure mechanical integrity of the electronic device 124 as a whole. The bottom-sided connections established by the electrically conductive connection medium 127 may allow for an electric signal transfer between the mounting base 132 and constituents of the package 100, in particular the electronic component 106 and the carrier 102. The top-sided connection established by the electrically conductive connection medium 129 may create a highly efficient thermal path from the electronic component 106 (which may be the main heat source during operation of the electronic device 124) through the carrier 102, through the heat sink 130 and from there towards an environment of the electronic device 124. The intermediate electrically conductive connection medium 128 may connect the electronic component 106 and the carrier 102, for instance may realize a die attach.

Thus, the electrically conductive connection media 127, 128, 129 may include the die to mounting base material (reference numeral 127), the die attach material (reference numeral 128) and heat sink attach material (reference numeral 129). In particular, the die attach may be a silver filled epoxy or hybrid sinter material or sinter material, the die to board attach material may be a solder, and the heat sink attach material may be a solder, for instance a different or similar alloy. The heat sink attach material may also be a sinter paste, etc.

More specifically, a wettable coating 108 coats an entire exterior surface of the carrier 102. By coating the entire exterior surface of the carrier 102 with the wettable coating 108, the wettable coating 108 promotes a reliable solder connection by electrically conductive connection medium 128 in an accommodation volume 104 between electronic component 106 and carrier 102, and at the bottom side of the carrier 102 with the mounting base 132. On the top side of the carrier 102, the wettable coating 108 promotes a reliable solder connection by electrically conductive connection medium 129 with respect to heat sink 130. The coating 108 provides a surface that enable a reliable solder interconnect between the heat sink 130 and the carrier 102, whilst also providing a surface that enables a reliable die attach interconnect between electronic component 106 and carrier 102. The coating 108 may also enable a reliable solder interconnect to be formed between the carrier 102 and the mounting base 132 (such as a substrate).

Advantageously, the wettable coating 108 is configured for wetting a (for example solder-type) electrically conductive connection medium 127, 128, 129. In particular, coating 108 provides a wettable surface for soldering and a reliable surface for die attach materials to adhere to. As shown in a detail 160, the wettable coating 108 may be embodied as a double layer comprising a first metal layer 156 and a second metal layer 158 on the first metal layer 156. For example, the first metal layer 156 may be a nickel layer. For instance, the second metal layer 158 may be a silver layer. The exterior surface of the wettable coating 108 may be configured for promoting wetting by the electrically conductive connection medium 127, 128, 129, in particular when embodied as solder (for instance comprising tin). Thus, the wettable coating 108 ensures a proper coating by the electrically conductive connection medium 127, 128, 129 and thus a very reliable connection between the various constituents of the electronic device 124 effected by the electrically conductive connection medium 127, 128, 129.

In the following, construction of the package 100 will be described in further detail:

In the embodiment of FIG. 1, package 100 comprises electrically conductive carrier 102 which is formed for delimiting an accommodation volume 104 or cavity therein. For example, carrier 102 may be a metal plate (for instance made of copper, an alloy comprising copper, aluminium, an alloy comprising aluminium, or an alloy of aluminium and copper) which is three-dimensionally bent so as to define the accommodation volume 104 or cavity for accommodating an electronic component 106. The carrier 102 can be can-shaped with a central planar plate section surrounded by at least two opposing sidewalls, preferably four sidewalls arranged along all four surrounding sides of the accommodation volume 104. According to FIG. 1, the carrier 102 is can-shaped and has two laterally and downwardly extending opposing rails 134, 136 (which may be denoted as drain rails) defining a transition portion 114. This transition portion 114 may equip the carrier 102 with a standoff for instance for keeping the bottom side of the electronic component 106 slightly spaced with respect to the mounting base 132 before establishing a solder connection in between. For instance, the carrier 102 may have a thickness D in a range from 100 μm to 500 μm, for example 250 μm. For example, carrier 102 may be embodied as a leadframe structure (for instance can be singulated as a can-section from a leadframe) or as a clip.

As already mentioned, the electronic component 106 is mounted on the carrier 102 and accommodated in the accommodation volume 104. In the shown embodiment, the package 100 comprises only one single electronic component 106 and is a discrete package. Although not shown, a package 100 may also comprise a plurality of electronic components 106 accommodated in the accommodation volume 104. Thus, package 100 may also be a multi-chip package. According to FIG. 1, electronic component 106 may be a semiconductor chip, for instance manufactured in silicon technology or silicon carbide technology. Electronic component 106 may be a power semiconductor chip. For example, the electronic component 106 may be a metal oxide semiconductor field-effect transistor (MOSFET) chip. Alternatively, the electronic component 106 may be an insulated gate bipolar transistor (IGBT) chip. As shown, the electronic component 106 has a plurality of exposed electrically conductive terminals 122, 123 on its bottom side and has one carrier-connected terminal 120 on its top side. For example, terminal 122 may be a gate terminal, terminals 123 may be source terminals, and terminal 120 may be a drain terminal of the field-effect transistor-type electronic component 106. Any other larger or smaller number of terminals on the top side and/or on the bottom side of the electronic component 106 is possible in other embodiments. In the embodiment of FIG. 1, the bottom-sided terminals 122, 123 are solder-connected to the mounting base 132, whereas the top-sided terminal 120 may be connected to the carrier 102. For instance, the die attach may be silver filled epoxy, hybrid sinter paste, sinter paste or diffusion soldering. Specifically in a DirectFET® application, the die attach may be silver filled epoxy. However, since carrier 102 is solder-connected to the mounting base 132 as well, also the top-sided terminal 120 is electrically connected with the mounting base 132 via the carrier 102.

As already mentioned, wettable coating 108 covering the entire exterior surface of the carrier 102 is highly advantageous for ensuring an efficient coating of the surface of the carrier 102 with electrically conductive connection medium 127, 128, 129, preferably solder. In particular, wettable coating 108 on the top side of the carrier 102 facing the heat sink 130 may be of utmost advantage since this makes possible to connect the heat sink 132 to the carrier 102 by a highly thermally conductive and mechanically properly reliable solder connection. A consequence of this is an excellent thermal performance of package 100. However, the excellent wettability of the wettable coating 108 may also lead to a pronounced tendency of flowable electrically conductive connection medium 129 to flow into undesired regions of the exterior surface of carrier 102. Without taking any further measures, it may in particular happen that flowable electrically conductive connection medium 129 (such as molten solder) may flow from the top side to the underside of the carrier 102. This may involve the risk of the formation of undesired electrically conductive paths and may unintentionally lead to an exterior appearance of the package 100 being not reproducible.

In order to suppress or even eliminate such undesired phenomena, it has turned out highly beneficially to provide a repelling structure 112 on a selected part of the exterior surface of the wettable coating 108 on the carrier 102. Said repelling structure 112 is configured, in particular is made of such a material and is located in such regions of the wettable coating 108, so that it is capable of efficiently repelling electrically conductive connection medium 129. In particular, the repelling structure 112 may prevent flowable electrically conductive connection medium 129 flowing along the wettable coating 108 to pass the repelling structure 112, which may thus act as a mechanical and chemical barrier for flowable electrically conductive connection medium 129. For this purpose, the repelling structure 112 is arranged on a surface portion of the carrier 102 facing away from the accommodation volume 104. The repelling structure 112 may be a circumferentially closed ring surrounding the entire electrically conductive connection medium 129 formed on top-sided heat removal surface 110 and carrying the heat sink 130. Since the accommodation volume 104 is formed on a bottom side of the carrier 102, the repelling structure 112 is arranged on the top side of the carrier 102 opposing the bottom-side. Preferably, the repelling structure 112 comprises a solder resist. As shown in FIG. 1, the repelling structure 112 may be arranged directly on the wettable coating 108. For example, the repelling structure 112 may be formed as an annularly closed or ring-shaped structure. In an embodiment, the repelling structure 112 may be formed by printing (for instance three-dimensional printing or ink jetting).

Advantageously, the repelling structure 112 of FIG. 1 is arranged on an exterior surface of a transition portion 114 between the top-sided heat removal surface 110 of the carrier 102, at which the carrier 102 is connected with the heat sink 130, and a bottom-sided surface of the carrier 102 delimiting the accommodation volume 104. As shown in FIG. 1, the transition portion 114 of the carrier 102 may be formed by curved and stepped sections. Beneficially, the repelling structure 112 is arranged on an upper platform 116 of the transition portion 114 retracted downwardly with respect to the heat removal surface 110. This has advantages: Firstly, arranging the repelling structure 112 on the transition portion 114 does not reduce the area of the heat removal surface 110 available for heat removal, in particular for assembling heat sink 130 thereon. This may ensure excellent thermal performance of the package 100. Secondly, arranging the repelling structure 112 on the transition portion 114 may prevent solder bleeding from the heat removal surface 110 downwardly along the transition portion 114 from reaching the underside of the carrier 102 and in particular the accommodation volume 104. As a result, the bottom side of the carrier 102 remains reliably free from creeping solder due to the described arrangement of the repelling structure 112. Thus, configuring the repelling structure 112 as a downset ring on the transition portion 114 may maximize the top-sided cooling area of the carrier 102 and may prevent creepage of solder from the top side onto the bottom side of the carrier 102.

In the embodiment of FIG. 1, a NiAg double layer is applied as wettable coating 108 also to the top side of the can-shaped carrier 102 to enable attachment of heat sink 130 by electrically conductive connection medium 129, which may comprise a solder, silver filled epoxy, or a sinter. In addition to the wettable coating 108 made of NiAg, it may also be highly advantageous to add solder mask-type repelling structure 112 to prevent overspill of solder material to the underside of the electronic component 108 into the underside of the carrier 102.

Thus, in the embodiment of FIG. 1, there may be a Ni/Ag coating on the outside of the can-shaped carrier 102, and on the inside of the can-shaped carrier 102. The additional solder mask constituting the repelling structure 112 may prevent solder from wetting down toward the inside of the can.

FIG. 2 illustrates a cross-sectional view of the package 100 of the electronic device 124 according to FIG. 1. FIG. 3 illustrates a plan view of the package 100 according to FIG. 2.

As shown in FIG. 3, the repelling structure 112 comprises a closed annular structure. By providing the repelling structure 112 as a circumferentially closed ring, bleeding of electrically conductive connection medium 129 (such as molten solder) may be reliably prevented along the entire perimeter of the carrier 102. This is in particular advantageous when the entire surface of the carrier 102 is coated by wettable coating 108 since this may promote solder flow in any direction.

More precisely, according to FIG. 2 and FIG. 3, the repelling structure 112 (in particular embodied as a solder mask) is provided as a ring that circles the first downset of the transition portion 114 of the can-shaped carrier 102. This combines a reliable protection against solder bleeding with a large area of heat removal surface 110 being not limited by the repelling structure 112.

The solder mask-type repelling structure 112 can be formed by inkjet printing and curing on the wettable coating 108. The can-shaped carrier 102 may be in leadframe form. Keeping the area of the solder mask sufficiently small and remote from the heat removal surface 110 may allow to boost the cooling capability of the package 100.

Locating the solder mask-type repelling structure 112 at the downset area of the transition portion 114 also maintains the planarity of the heat removal surface 110 being fully usable for heat removal purposes, for instance for connecting heat sink 130 thereon by soldering.

As can be taken from FIG. 2, the terminals on the bottom main surface of the electronic component 106 may be covered with solder balls or solder bumps forming the electrically conductive connection medium 127 on the bottom side of the electronic component 106. Between adjacent structures of electrically conductive connection medium 127, the bottom side of the electronic component 106 may be equipped with a patterned electrically insulating passivation layer 162. For instance, passivation layer 162 may be denoted as a chip level solder mask.

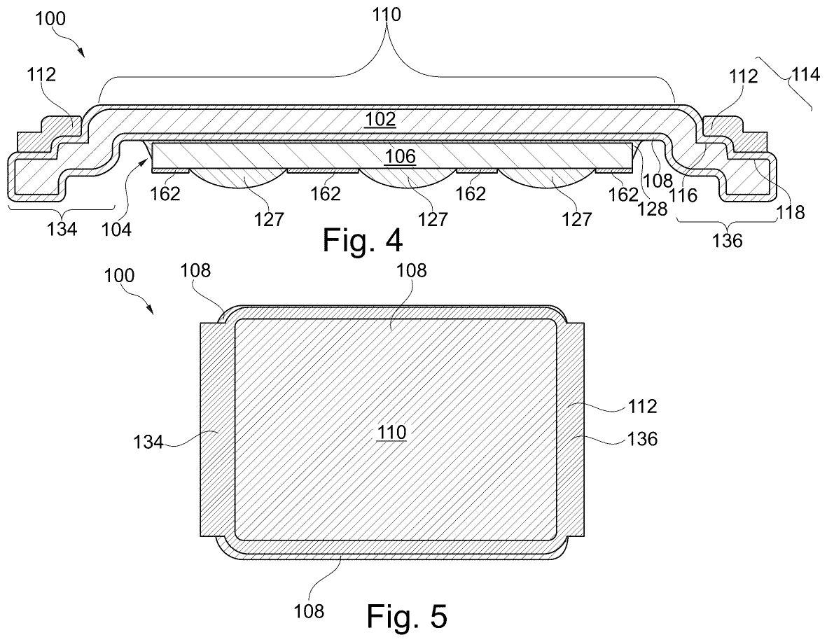

FIG. 4 illustrates a cross-sectional view of a package 100 according to another exemplary embodiment. FIG. 5 illustrates a plan view of the package 100 according to FIG. 4.

The embodiment according to FIG. 4 and FIG. 5 differs from the embodiment of FIG. 2 and FIG. 3 in particular in that, according to FIG. 4 and FIG. 5, the repelling structure 112 extends from the upper platform 116 of transition portion 114 up to and including a lower platform 118 of the transition portion 114. As shown in FIG. 5, the repelling structure 112 may be formed on the entire top surface of both opposing rails 134, 136 of the carrier 102.

As shown in FIG. 4 and FIG. 5, the solder mask-type repelling structure 112 can be jetted to cover the drain edges as well to prevent solder moving up the drain rails 134, 136. The embodiment of FIG. 4 and FIG. 5 provides a highly reliable protection against solder bleeding without compromising on the area of the heat removal surface 110. Thus, no reduction of the cooling area capability and no reduction of the planarity of the package 100 will occur with the embodiment of FIG. 4 and FIG. 5. Apart from this, the embodiment of FIG. 4 and FIG. 5 may lead to an increased and more complex moisture path so that the repelling structure 112 may also protect the package 100 against moisture creepage.

FIG. 6 illustrates a cross-sectional view of a package 100 according to another exemplary embodiment. FIG. 7 illustrates a plan view of the package 100 according to FIG. 6.

The embodiment according to FIG. 6 and FIG. 7 differs from the embodiment of FIG. 2 and FIG. 3 in particular in that, according to FIG. 6 and FIG. 7, the repelling structure 112 is arranged on a top-sided exterior planar area of the heat removal surface 110 of carrier 102. In other words, the repelling structure 112 of FIG. 6 and FIG. 7 may be formed on the same vertical level as the heat removal surface 110.

Thus, the soldermask-type repelling structure 112 can be jetted to cover just the back side of the carrier 102 and the wettable coating 108 thereon. This may lead to a very simple application process for forming the repelling structure 112.

FIG. 8 illustrates a top-sided three-dimensional view of a carrier 102 with an accommodation volume 104 of a package 100 according to another exemplary embodiment. FIG. 9 illustrates a bottom-sided three-dimensional view of the carrier 102 with indented accommodation volume 104 of the package 100 according to FIG. 8. FIG. 8 and FIG. 9 do not show an electronic component, just the carrier 102.

Thus, the metallic carrier 102 shown in FIG. 8 and FIG. 9 comprises a central can-region 164 with a cavity-type accommodation volume 104 surrounded by four stepped, slanted or vertical sidewalls 166. From two opposing of said sidewalls 166, bar-shaped rails 134, 136 extend laterally outwardly.

FIG. 10 illustrates a flowchart 200 of a method of manufacturing a package 100 according to an exemplary embodiment. The reference signs used for the following description of said manufacturing method relate to the embodiments of FIG. 1 and FIG. 9.

Referring to a block 202, the method comprises providing an at least partially electrically conductive carrier 102 which is formed for delimiting an accommodation volume 104 therein.

Referring to a block 204, the method comprises mounting an electronic component 106 on the carrier 102 and accommodated at least partially in the accommodation volume 104.

Referring to a block 206, the method comprises forming a repelling structure 112 configured for repelling an electrically conductive connection medium 127, 128, 129.

Referring to a block 208, the method comprises arranging the repelling structure 112 on part of a surface of the carrier 102 facing away from the accommodation volume 104.

With ink jetting, the processes of forming and arranging may be the same (for example, the material may be dispensed where it is jetted). However, when dip coating or spray coating the material, additional processes such as dry, expose/develop/bake may be executed to pattern the solder mask. With this in mind, for ink jetting, stages 206 and 208 may be combined into one.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A package, comprising:
an at least partially electrically conductive carrier which is formed for delimiting an accommodation volume therein;
an electronic component mounted on the carrier and accommodated at least partially in the accommodation volume; and
a repelling structure configured for repelling an electrically conductive connection medium and being arranged on part of a surface of the carrier facing away from the accommodation volume.

2. The package according to claim 1, comprising a wettable coating configured for being wettable by an electrically conductive connection medium and being arranged at least on part of a heat removal surface of the carrier facing away from the accommodation volume.

3. The package according to claim 2, wherein the wettable coating also coats at least part of a surface of the carrier facing away from the heat removal surface and delimiting the accommodation volume.

4. The package according to claim 2, wherein the wettable coating coats an entire exterior surface of the carrier.

5. The package according to claim 2, wherein the wettable coating is configured for wetting a solder-type electrically conductive connection medium.

6. The package according to claim 2, wherein the wettable coating comprises silver and/or nickel.

7. The package according to claim 1, wherein the repelling structure is formed at least on at least part of each of two opposing rails of the carrier.

8. The package according to claim 1, wherein the repelling structure comprises a closed annular structure.

9. The package according to claim 1, wherein the repelling structure comprises a solder resist.

10. The package according to claim 2, wherein the repelling structure is arranged on the wettable coating.

11. The package according to claim 1, wherein the repelling structure is arranged on an exterior surface of a transition portion between a, preferably planar, exterior heat removal surface of the carrier and an interior surface of the carrier delimiting the accommodation volume.

12. The package according to claim 11, wherein the transition portion of the carrier is curved and/or stepped.

13. The package according to claim 11, wherein the repelling structure is arranged on an upper platform of the transition portion retracted downwardly with respect to the heat removal surface.

14. The package according to claim 13, wherein the repelling structure extends from the upper platform up to and including a lower platform of the transition portion.

15. The package according to claim 1, wherein the repelling structure is arranged on a planar area of the heat removal surface.

16. The package according to claim 1, comprising at least one of the following features:
the electronic component comprises at least one carrier-connected terminal on one main surface on which the electronic component is mounted on the carrier;
the electronic component comprises at least one exposed terminal, for example a plurality of exposed terminals, facing away from the carrier;
the carrier is can-shaped;
the carrier has two opposing rails;
the carrier comprises a leadframe structure, a clip and/or a bent metallic plate;
the package is configured as a discrete package;
the package is configured as a non-encapsulated package;
the package is configured as a power package;
the electronic component is a power semiconductor chip;
the electronic component comprises a monolithically integrated transistor, in particular a field-effect transistor.

17. An electronic device, comprising:
a package according to claim 1; and
an assembly structure assembled with the package.

18. The electronic device according to claim 17, comprising at least one of the following features:
comprising an electrically conductive connection medium electrically connecting the package with the assembly structure, wherein the electrically conductive connection medium comprises a solder, a sinter material and/or an electrically conductive glue;
wherein the assembly structure comprises a heat sink mounted on a heat removal surface of the carrier;
wherein the assembly structure comprises a mounting base, the mounting base comprising a laminate board, on which the carrier and/or the electronic component is or are mounted.

19. A method of manufacturing a package, wherein the method comprises:
providing an at least partially electrically conductive carrier which is formed for delimiting an accommodation volume therein;
mounting an electronic component on the carrier and accommodated at least partially in the accommodation volume;
forming a repelling structure configured for repelling an electrically conductive connection medium; and
arranging the repelling structure on part of a surface of the carrier facing away from the accommodation volume.

20. The method according to claim 19, wherein the method comprises forming the repelling structure by printing, for example inkjet printing or three-dimensional printing, optionally followed by curing.
